(19) United States
(12) Patent Application Publication
(10) Pub. No.: US 2008/0084771 A1
(43) Pub. Date: Apr. 10, 2008

(54) Semiconductor device

(75) Inventor: Kazuhiko Kajigaya, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 11/905,723

(22) Filed: Oct. 3, 2007

(30) Foreign Application Priority Data
Oct. 6, 2006 (JP) 2006-275823

(51) Int. Cl. G11C 29/00; G11C 7/00; G11C 8/00

(52) U.S. Cl. 365/200; 365/205; 365/230.03

(57) ABSTRACT

A semiconductor device of the invention comprises: a plurality of unit blocks aligned at least in a bit line extending direction, into which a memory cell array is divided; a plurality of sense amplifiers provided in each of the unit blocks for amplifying data of memory cells through bit lines; a switch circuit capable of switching connection between an input/output port for inputting/outputting data of the unit blocks and the plurality of sense amplifiers; and a redundancy select circuit for controlling the switch circuit so as to maintain connection relation between the input/output port and a predetermined number of the sense amplifiers from which one or more sense amplifiers each corresponding to a defective bit line having a defective memory cell are excluded, in accordance with defect information specifying the defective memory cell in the unit blocks.

### BACKGROUND OF THE INVENTION

1. Field of the Invention

The present invention relates to a semiconductor device having a relief circuit for relieving defective memory cells in a memory cell array, and particularly relates to a semiconductor device having a memory cell array employing a shift redundancy relief method.

2. Description of the Related Art

For the purpose of improving a yield of a semiconductor memory such as DRAM, a configuration in which a relief circuit for relieving defects generated in production process is added to a memory circuit is employed. By using such a relief circuit, a defective memory cell detected in testing the DRAM can be replaced with a redundant memory cell. A relief method applicable to a general DRAM is generally such that a defective address is beforehand stored and compared with an input address by an address comparison circuit, and when the comparison result matches, the defective cell is replaced with the redundant memory cell.

Meanwhile, as semiconductor devices achieve multiple functions and are highly integrated, a semiconductor device in which the memory circuit and other logic circuits are mixed on a single chip is required as well as the general DRAM. When a DRAM circuit and a logic circuit are mixed, data having a wide bit width should be transferred therebetween in high-speed. However, since operation of the address comparison circuit takes time for the DRAM to which the above general relief method is applied, high-speed data transfer is hindered. As a relief method without the address comparison circuit, a shift redundancy relief method is known (for example, see Japanese Patent Laid-Open No. 2001-93293). In the shift redundancy relief method, by controlling connection between a plurality of bit lines and input/output lines, the connection relation is controlled to be shifted around a defective bit line on which the defective memory cell is detected so as to be suitable for high-speed operation.

As storage capacity of DRAM becomes larger in recent years, memory mats (unit block) as access units in the memory cell array are finely partitioned and a configuration in which the memory cell array is divided into a large number of memory mats is generalized. In such DRAM, a column decoder and select control lines for column circuits are generally configured to be commonly arranged for all the memory mats. Therefore, when applying the shift redundancy relief method, a relief circuit including redundant bit lines, a switch circuit and a fuse circuit is commonly arranged for all the memory mats. However, in the DRAM configured in this manner, if there is the defective bit line in a certain memory mat, a corresponding bit line is replaced with a redundant bit line in all the memory mats. Thereby, a large number of normal bit lines are correspondingly replaced. Accordingly, if the shift redundancy relief method is applied to the DRAM which is divided into a plurality of memory mats, this causes a problem of reducing relief efficiency and increasing cost.

### BRIEF SUMMARY OF THE INVENTION

An object of the present invention is to provide a semiconductor device having a relief circuit capable of high-speed access without reduction of relief efficiency when applying the shift redundancy relief method to the memory cell array which is divided into a plurality of unit blocks.

An aspect of the present invention is a semiconductor device having a memory cell array in which a plurality of memory cells are formed at intersections between a plurality of word lines and a plurality of bit lines, comprising: a plurality of unit blocks aligned at least in a bit line extending direction, into which the memory cell array is divided; a plurality of sense amplifiers provided in each of said unit blocks for amplifying data of the memory cells through the bit lines; a switch circuit capable of switching connection between an input/output port for inputting/outputting data of said unit blocks and said plurality of sense amplifiers; and a redundancy select circuit for controlling said switch circuit so as to maintain connection relation between the input/output port and a predetermined number of the sense amplifiers from which one or more sense amplifiers each corresponding to a defective bit line having a defective memory cell are excluded, in accordance with defect information specifying the defective memory cell in said unit blocks.

According to the semiconductor device of the present invention, the switch circuit is arranged for switching the plurality of sense amplifiers and the input/output port for each unit block to which the memory cell array is divided, and is controlled and switched by the redundancy select circuit so that the connection relation is maintained in accordance with the defect information. Therefore, a relief circuit for relieving a defective bit line by replacing with a redundancy circuit is not shared by the entire memory cell array while being provided individually for each unit block so as to relieve the defective bit line for each unit block. Accordingly, when the shift redundancy relief method is applied to the memory cell array being divided into a plurality of the unit blocks, the defect can be relieved in low cost and high reliability while maintaining high-speed access and effectively preventing a reduction in relief efficiency.

In the present invention, said redundancy select circuit may be connected to said switch circuit through a node between adjacent fuses among a plurality of fuses connected in series between a power supply and ground, and may be configured such that one fuse selected based on said defect information is cut.

In the present invention, two bit lines as a complementary pair may constitute a bit line pair, the memory cell may be formed at one of two intersections between the bit line pair and the word line, and each of the sense amplifiers may be arranged corresponding to the bit line pair.

In the present invention, the input/output port may have a plurality of terminals and a pair of the terminals corresponding to the bit line pair may transmit one bit through the sense amplifier.

The present invention may further comprise a column decoder for selectively activating a plurality of select control lines extending along the plurality of bit lines in response to an input column address, and said switch circuit may include a plurality of first switches capable of switching connection between the sense amplifier and the pair of the terminals in response to the select control line selected among adjacent two select control lines by said redundancy select circuit.

The present invention may further comprise a column decoder for selectively activating a plurality of select control lines extending in an intersecting direction of the plurality of bit lines in response to an input column address, and said switch circuit may include a plurality of second switches capable of switching connection between the terminal selected among adjacent two pairs of terminals by said redundancy select circuit and the sense amplifier in response to the select control line commonly connected thereto.

In the present invention, said plurality of sense amplifiers, said switch circuit and said redundancy select circuit may be symmetrically arranged at both ends in a bit line extending direction of said unit blocks, and each of the bit line pair may be connected to one of the sense amplifiers at the both ends. In this case, said plurality of sense amplifiers, said switch circuit and said redundancy select circuit may be shared by adjacent two of said unit blocks.

In the present invention, one bit line pair and one sense amplifier among the N+1 bit line pairs and corresponding N+1 said sense amplifiers may be provided as a redundancy circuit, and said redundancy select circuit may control said switch circuit so as to maintain connection relation between N said sense amplifiers and the input/output port by replacing one defective bit line pair and one corresponding sense amplifier with the redundancy circuit.

Another aspect of the present invention is a semiconductor device having a memory cell array in which a plurality of memory cells are formed at intersections between a plurality of word lines and a plurality of bit lines, comprising: a plurality of unit blocks aligned at least in a bit line extending direction, into which the memory cell array is divided; a plurality of sense amplifiers provided in each of said unit blocks for amplifying data of the memory cells through the bit lines; a first switch circuit capable of switching connection between a first input/output port for inputting/outputting data of said unit blocks and said plurality of sense amplifiers; a second switch circuit capable of switching connection between a second input/output port for inputting/outputting data of said unit blocks and said plurality of sense amplifiers; and a redundancy select circuit for controlling said first switch circuit so as to maintain connection relation between the first input/output port and a predetermined number of the sense amplifiers from which one or more sense amplifiers each corresponding to a defective bit line having a defective memory cell are excluded, and connection relation between the second input/output port and the predetermined number of the sense amplifiers, in accordance with defect information specifying the defective memory cell in said unit blocks.

The present invention may further comprise: a first column decoder for selectively activating a plurality of first select control lines extending along the plurality of bit lines in response to an input column address; and a second column decoder for selectively activating a plurality of second select control lines extending in an intersecting direction of the plurality of bit lines in response to an input column address, and said first switch circuit maybe switched by the first select control lines while said second switch circuit may be switched by the second select control lines.

In the present invention, a bit width of the second input/output port may be larger than a bit width of the first bit input/output port.

In the present invention, a memory block including said unit blocks, said plurality of sense amplifiers, said first switch circuit, said second switch circuit and said redundancy select circuit may be configured, and a memory circuit may be configured by arranging said first column decoder and said second column decoder for a plurality of the memory blocks. In this case, the plurality of the memory blocks may be arranged in a bit line extending direction and in a direction orthogonal to the bit lines, the respective first input/output ports thereof may be connected to one another through common input/output lines, and the respective second input/output ports thereof may be connected to one another through common input/output lines. Further, the first input/output port may be connected to outside and the second input/output port may be connected to an internal logic circuit.

As described above, according to the present invention, the plurality of sense amplifiers, the switch circuit and the redundancy select circuit are added to each of the plurality of the unit blocks into which the memory cell array is divided, and thereby the relief circuit for the defective bit line is configured. Thus, when applying the shift redundancy relief method which does not require an address comparison, the relief circuit is provided for the unit block in which the subdivided length thereof in a bit line extending direction is shortened compared with the entire memory cell array, and therefore the relief efficiency of the defective bit line can be improved. Particularly, when applying to a semiconductor device in which a memory circuit and a logic circuit is mixed, a low cost and high performance semiconductor device can be realized, in which high-speed data transfer between the memory circuit and the logic circuit is performed because the address comparison is not required.

### BRIEF DESCRIPTION OF THE DRAWINGS

The above and other objects and features of the invention will appear more fully hereinafter from a consideration of the following description taken in connection with the accompanying drawing wherein one example is illustrated by way of example, in which;

FIG. 1 is a block diagram showing a schematic configuration of a DRAM of a first embodiment;

FIG. 2 is a diagram showing a principal configuration including a detailed configuration of a memory mat 10 of the DRAM in the first embodiment;

FIG. 3 is a diagram showing a principal configuration of a detailed configuration of a mat peripheral column circuits on both sides of the memory mat 10 in the DRAM of the first embodiment;

FIG. 4 is a diagram showing a circuit configuration of a first switch SW1 of a switch circuit 21 in an enlarged scale;

FIG. 5 is a diagram showing relations of defective memory cells, cut fuses F and control states of the first switch SW1 regarding a relief operation of the first embodiment;

FIG. 6 is a connection state diagram corresponding to a state 1A of FIG. 5;

FIG. 7 is a connection state diagram corresponding to a state 1B of FIG. 5;

FIG. 8 is a connection state diagram corresponding to a state 1C of FIG. 5;

FIG. 9 is a connection state diagram corresponding to a state 1D of FIG. 5;

FIG. 10 is a connection state diagram corresponding to a state 1E of FIG. 5;

FIG. 11 is a block diagram showing a schematic configuration of a DRAM of a second embodiment;

FIG. 12 is a diagram showing a principal configuration of the DRAM of the second embodiment;

FIG. 13 is a diagram showing a circuit configuration of a second switch SW2 of a switch circuit 41 in an enlarged scale;

FIG. 14 is a diagram showing relations of defective memory cells, cut fuses F and control states of the second switch SW2 regarding a relief operation of the second embodiment;

FIG. 15 is a connection state diagram corresponding to a state 2A of FIG. 14;

FIG. 16 is a connection state diagram corresponding to a state 2B of FIG. 14;

FIG. 17 is a connection state diagram corresponding to a state 2C of FIG. 14;

FIG. 18 is a connection state diagram corresponding to a state 2D of FIG. 14;

FIG. 19 is a connection state diagram corresponding to a state 2E of FIG. 14;

FIG. 20 is a diagram showing a principal configuration of a DRAM of a third embodiment;

FIG. 21 is a diagram showing a configuration example of a DRAM macro circuit in which sixteen memory blocks MB are arranged;

FIG. 22 is a diagram showing an example of an entire configuration of a semiconductor device including the DRAM macro circuit of FIG. 21; and

FIGS. 23A and 23B are diagrams for explaining an example of a system using the semiconductor device of FIG. 22 in comparison with a conventional configuration.

### DETAILED DESCRIPTION OF THE INVENTION

Preferred embodiments of the present invention will be described with reference to the accompanying drawings. Hereinafter, first to third embodiments will be described in which the present invention is applied to a semiconductor device configured by a DRAM as a semiconductor memory device mixed with a logic circuit.

### First Embodiment

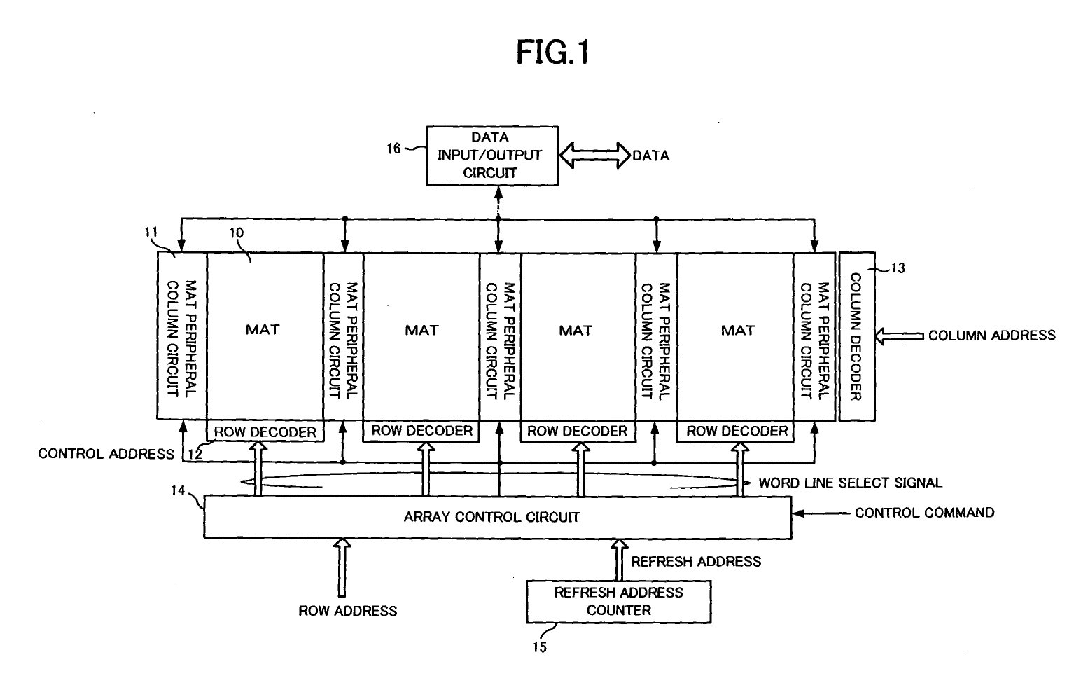

In the first embodiment, a case of applying the present invention to a DRAM having a general input/output interface will be described. FIG. 1 is a diagram showing a schematic configuration of the DRAM of the first embodiment. The DRAM shown in FIG. 1 includes four memory mats 10, five mat peripheral column circuits 11 each adjacent to the memory mats 10, four row decoders 12 for each memory mat 10, a column decoder 13, an array control circuit 14, a refresh address counter 15 and a data input/output circuit 16. An actual memory cell array is divided into a plurality of banks each having a predetermined number of memory mats 10 and operation is controlled for each bank, but the bank division is not shown in FIG. 1.

The memory mat 10 is a unit block into which the memory cell array is divided, and includes a large number of memory cells formed at intersections between a plurality of bit lines and a plurality of word lines intersecting therewith. As shown in FIG. 1, four memory mats 10 are aligned in a bit line extending direction. In the first embodiment, redundant memory cells for relieving defective memory cells are provided on one or two bit line pairs in each memory mat 10. A certain bit line pair on which a defective memory cell is actually detected is replaced with the above-mentioned bit line pair having the redundant memory cells based on a configuration described later.

Meanwhile, mat peripheral column circuits 11 including column circuits such as sense amplifiers and switch circuits are arranged on both sides of the memory mats 10. Three mat peripheral column circuits 11 except two at both ends are shared by adjacent two memory mats 10. On the other hands, each of two mat peripheral column circuits 11 at the both ends is attached only to a single memory mat 10. This is configured on the assumption of employing the shared sense amplifier scheme.

Each of the four row decoders 12 in arranged at one end in a word line extending direction of each memory mat 10, and selects a word line corresponding to an input row address for each memory mat 10. The column decoder 13 is arranged at one end in a bit line extending direction of the four memory mats 10, and selects a bit line corresponding to an input column address. In the configuration of FIG. 1, a plurality of select control lines for selecting a bit line is commonly arranged from the column decoder 13 to each memory mat 10, and its detailed configuration will be described later.

The array control circuit 14 controls operations of the memory mats 10 and the mat peripheral column circuits 11 according to control commands from outside. Further, the array control circuit 14 supplies a word line select signal based on the row address to each row decoder 12, and supplies a control signal for operation control to each mat peripheral column circuit 11. The refresh address counter 15 counts up a refresh address corresponding to a word line to be refreshed, and sends the refresh address to the array control circuit 14.

The data input/output circuit 16 inputs/outputs read data or write data corresponding to the column address for each memory mat 10 from/to the outside via each mat peripheral column circuit 11. In the first embodiment, data input/output from/to the data input/output circuit 16 has a narrow bit width as described later, in accordance with the general input/output interface.

Although the configuration in which the four memory mats 10 are aligned in the example of FIG. 1 is shown, the number of memory mats 10 is not limited to four, and the present invention can be applied to a configuration including N memory mats 10 aligned in a bit line extending direction, N−1 mat peripheral column circuits 11 each of which is shared by adjacent two memory mats 10, and two mat peripheral column circuits 11 located at the both ends.

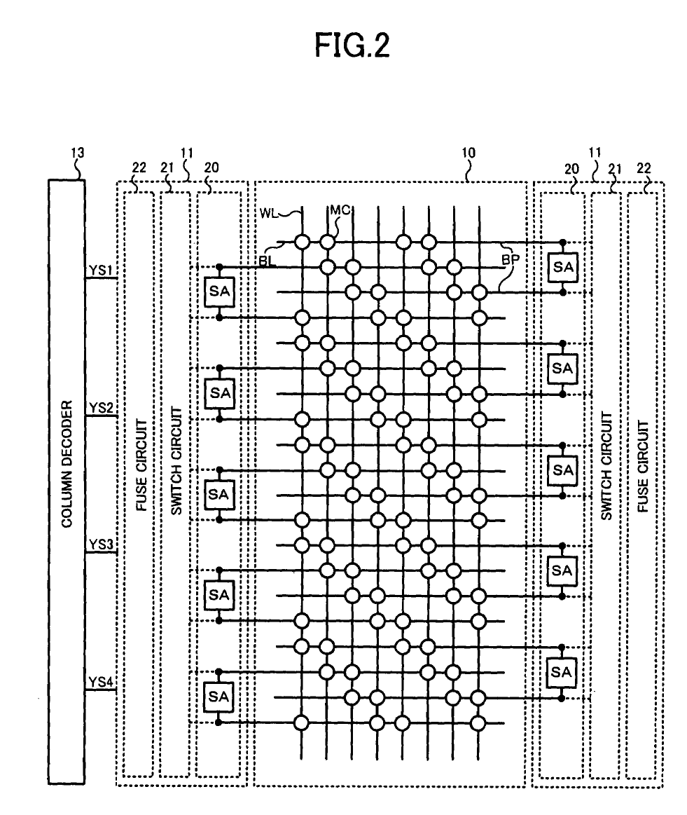

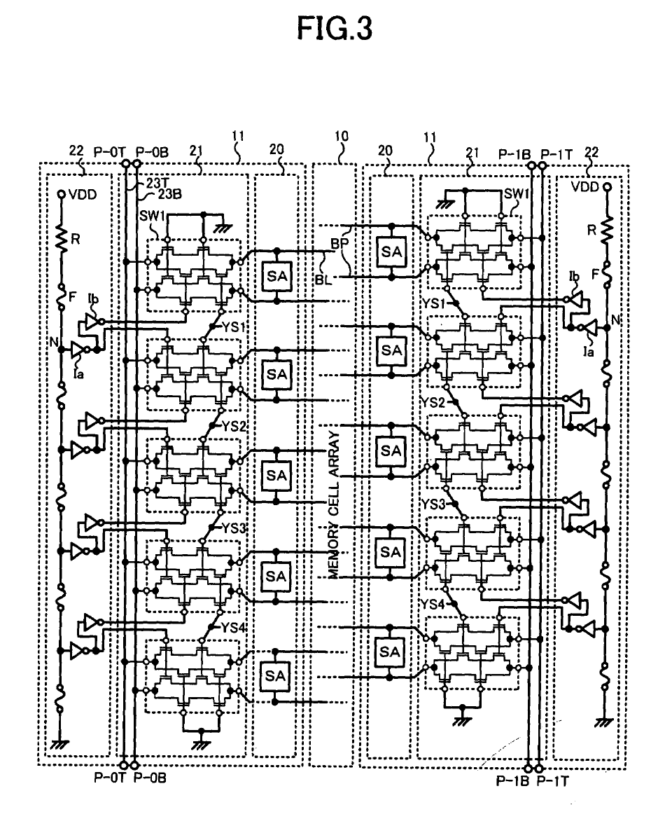

A principal configuration of the DRAM of the first embodiment will be described with reference to FIGS. 2 and 3. In the following, a circuit portion including one memory cell array 10, two mat peripheral column circuits 11 on both sides thereof and the column decoder 13 in the configuration of FIG. 1 will be specifically described. FIG. 2 corresponds to a detailed configuration of the memory mat 10, and FIG. 3 corresponds to a detailed configuration of the mat peripheral column circuits 11. In addition, the mat peripheral column circuit 11 is divided into a sense amplifier circuit 20, a switch circuit 21 and a fuse circuit 22.

As shown in FIG. 2, a plurality of word lines WL and a plurality of bit lines BL intersecting therewith are arranged in the memory mat 10, and a large number of memory cells MC are formed at intersections between the word lines WL and the bit lines BL. In FIG. 2, an example of arranging 8 word lines WL and 20 bit lines BL in the memory mat 10 is shown for the convenience of explanation, however the memory mat 10 is configured by arranging a larger number of word lines WL and bit lines BL.

Two bit lines BL as a complementary pair constitute a bit line pair BP. As shown in FIG. 2, a single memory cell MC is formed at one of two intersections between each bit line pair BP and one word line WL. Accordingly, since there are 160 (8×20) intersections in FIG. 2, half 80 memory cells MC are formed. Generally, when m word lines WL and n bit lines BL are arranged in the memory mat 10, m×n/2 memory cells MC are formed so that data of m×n/2 bits in total can be stored. The arrangement pattern for the intersections of memory cells MC of FIG. 2 is an example, and thus a variety of arrangement patterns capable of storing the same data can be employed.

The respective sense amplifier circuit 20 includes a plurality of sense amplifiers SA corresponding to five bit line pairs BP. That is, two bit lines BL arranged on every other line constitute the bit line pair so that 10 bit line pairs are constituted in total, five bit line pairs BP of which are connected to five sense amplifiers SA on the left side, and the remaining five bit line pairs BP of which are connected to five sense amplifiers SA of the right side. Each sense amplifier SA operates to amplify a minute potential generated due to accumulate charge of the memory cell MC through the connected bit line pair BP and to rewrite it to the memory cell MC.

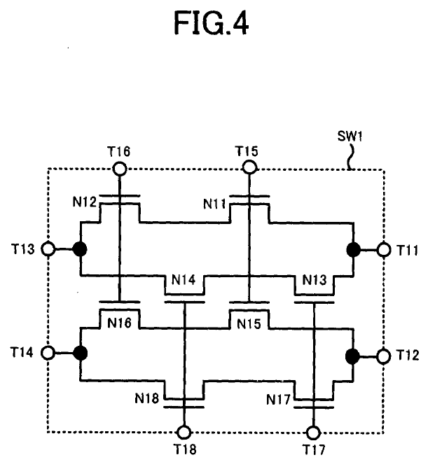

The switch circuit 21 of FIG. 3 includes a plurality of first switches SW1 each corresponding to the bit line pair BP. Each first switch SW1 is arranged for controlling a connection state between both ends of the sense amplifier SA corresponding to the bit line pair BP and a pair of input/output lines 23T and 23B connected to an input/output port. Herein, a circuit configuration of the first switch SW1 is shown in an enlarged scale in FIG. 4.

As shown in FIG. 4, the first switch SW1 is composed of eight NMOS transistors N11 to N18, one pair of input terminals T11 and T12, one pair of output terminals T13 and T14, and four terminals T15, T16, T17, T18 for controlling are provided therein. The input terminals T11 and T12 are connected to both ends of the sense amplifier SA, and the output terminals T13 and T14 are connected to one pair of input/output lines 23T and 23B. One input terminal T11 and one output terminal T13 are connected through a first path which is formed by series-connected two NMOS transistors N11 and N12 and a second path which is formed by series-connected two NMOS transistors N13 and N14. Further, the other input terminal T12 and the other output terminal T14 are connected through a first path which is formed by series-connected two NMOS transistors N15 and N16 and a second path which is formed by series-connected two NMOS transistors N17 and N18.

The terminal T15 is connected to the gates of two NMOS transistors N11 and N15, and the terminal T16 is connected to the gates of two NMOS transistors N12 and N16. The terminal T17 is connected to the gates of two NMOS transistors N13 and N17, and the terminal T18 is connected to the gates of two NMOS transistors N14 and N18. By such a configuration, two paths from the input to the output are controlled to be switched. First, when upper terminals T15 and T16 are both controlled to be high and at least one of lower terminals T17 and T18 is controlled to be low, the input terminals T11 and T12 and the output terminals T13 and T14 are connected through the above-mentioned first paths. On the other hand, when the lower terminals T17 and T18 are both controlled to be high and at least one of the upper terminals T15 and T16 is controlled to be low, the input terminals T11 and T12 and the output terminals T13 and T14 are connected through the above-mentioned second paths.

In addition, in a writing operation for the memory mat 10, input/output relation of the first switch SW1 is reversed so that the input terminals T11 and T12 function as output terminals and the output terminals T13 and T14 function as input terminals.

Returning to FIG. 3, connection between the both ends of the sense amplifier SA connected to the input terminals T11 and T12 and the input/output lines 23T and 23B connected to the output terminals T13 and T14 can be switched to either of the first and second paths by the first switch SW1 configured as in FIG. 4. By appropriately controlling the states of the terminals T15 to T18 of the five first switches SW1 included in each switch circuit 21, one of five bit line pairs BP can be always maintained in a state of being disconnected from the input/output lines 23T and 23B, as described later. In the switch circuits 21 on the both sides, the first switches SW1 have a symmetrical connection relation.

Four select control lines YS1 to YS4 are output from the column decoder 13 shown in FIG. 2, and one of the select control lines YS1 to YS4 is selectively activated in response to the column address. The four select control lines YS1 to YS4 extend approximately along the direction of the bit lines BL, and are connected to one terminal T15 (upper side of FIG. 3) and the other terminal T17 (lower side of FIG. 3) of the adjacent two first switches SW1 in the first switch circuit 21. Due to the symmetry of the first switches SW1 on the both sides, each of the select control lines YS1 to YS4 is connected to four terminals T15 or T17 in total.

One pair of the input/output lines 23T and 23B shown in FIG. 3 extends in a direction approximately orthogonal to the direction of the bit lines BL, and one ends thereof are defined as an input/output port. That is, the input/output port transmitting one bit is composed of a terminal P-0T corresponding to one input/output line 23T and a terminal P-0B corresponding to the other input/output line 23B. Data of one bit line pair BP selected by the switch circuit 21 is transmitted to/from the input/output port through the input/output lines 23T and 23B. The input/output lines 23T and 23B and the input/output port are arranged symmetrically for the switch circuits 21 on the both sides, and are connected to an external common node (not shown).

The fuse circuit 22 of FIG. 3 includes five fuses F which are selectively cut in accordance with defect information obtained in testing the memory cell array 10, and functions as the redundancy select circuit of the invention. The five fuses F are series connected between a resistor R connected to a power supply and ground, and a node N between adjacent two fuses F is connected to an input of two-stage inverters Ia and Ib connected in series. In the adjacent two first switches SW1, an output of the first-stage inverter Ia is connected to the terminal T16 of one first switch SW1, and an output of the last-stage inverter Ib is connected to the terminal T18 of the other first switch SW1.

One fuse F is cut, which is selected from the five fuses F in accordance with the detection result of the defective memory cell in testing the semiconductor device. For example, a method is known in which the target fuse F is heated by applying a laser beam from outside so as to be cut. When the five fuses F are in a non-cut state, all the above nodes N are maintained low. When any of the fuses F is cut, upper nodes N go high via the resistor R while lower nodes N go low, on the basis of the cut position.

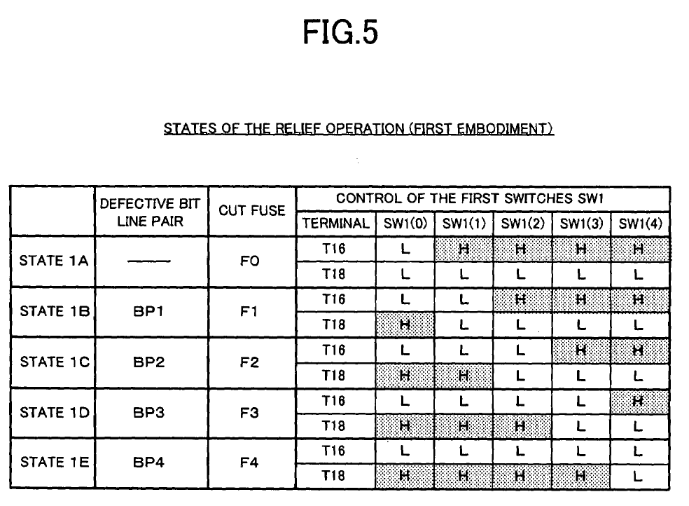

A relief operation of the mat peripheral column circuit 11 which is controlled based on the state of the fuse circuit 22 and switching of the switch circuit 21 will be described using FIGS. 5 to 10. In a table of FIG. 5, there are shown relations of positions of detected defective memory cells, positions of the bit line pairs BP, cut fuses F, control states of the terminals T16 and T18 of the first switch SW1. Here, five bit line pairs BP, five first switches SW1 and five fuses F are respectively represented with numbers. In FIG. 5, the bit line pairs BP connected to the left side sense amplifier circuit 20 are denoted by bit line pairs BP0, BP1, BP2, BP3 and BP4 from the upper side of FIG. 3, the five first switches SW1 are denoted by SW1(0), SW1(1), SW1(2), SW1(3) and SW1(4) from the upper side of FIG. 3, and the five fuses F are denoted by F0, F1, F2, F3 and F4 from the upper side of FIG. 3.

A state 1A shown in FIG. 5 corresponds to a case in which a bit line pair BP having a defective memory cell does not exist, and the uppermost fuse F0 is cut. Four nodes N is low regardless of whether or not the fuse F0 is cut, however the fuse F0 is cut to prevent waste current flowing through the resistor R in this case. In the state 1A, each terminal T16 of four first switches SW1(1) to SW1(4) is controlled to be high through the inverter Ia, and each terminal T18 of the four first switches SW1(0) to SW1(3) is controlled to be low through the inverter Ib. As shown in FIG. 3, the terminal T16 of the first switch SW1(0) and the terminal T18 of the first switch SW1(4) are both fixed to low.

Meanwhile, states 1B to 1E shown in FIG. 5 correspond to cases in which a defective memory cell is detected on any of bit line pairs BP1 to BP4, and any of fuses F1 to F4 having the corresponding number is cut. Since the uppermost bit line pair BP0 and a corresponding sense amplifier SA are provided as a redundancy circuit, these are controlled according to the state 1A even if the defective memory cell exists.

As shown in FIG. 5, as the position of the cut fuse F corresponding to the defective bit line pair changes, states of the terminals T16 and T18 change for the five first switches SW1(0) to SW1(4). In other words, terminals T16 and T18 of the first switch SW1 corresponding to the number of the cut fuse F are both controlled to be low, and on the basis of this position, first switches SW1 having smaller numbers are controlled so that the terminal T16 is low and the terminal T18 is high while first switches SW1 having larger numbers are controlled so that the terminal T16 is high and the terminal T18 is low.

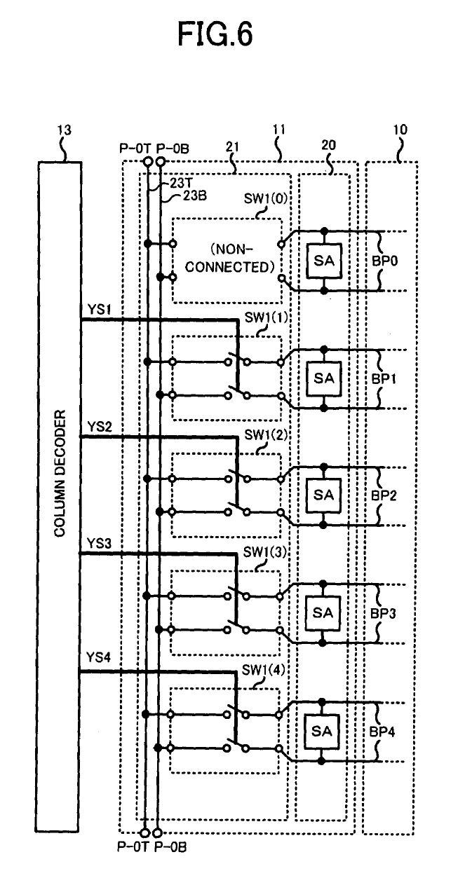

FIGS. 6 to 10 show connection states each equivalent to a circuit configuration of the left side mat peripheral column circuit 11 when the respective states 1A to 1E are controlled corresponding to the table of FIG. 5. FIG. 6 is a connection state diagram corresponding to the state 1A of FIG. 5. In FIG. 6, the four select control lines YS1 to YS4 output from the column decoder 13 are controlled to switch the four first switches SW1(1) to SW1(4) except the uppermost first switch SW1(0). Then, when one of the select control lines YS1 to YS4 is selected, a corresponding path of the first switch SW1 is formed and both ends of the sense amplifier SA are directly connected to a pair of the input/output lines 23T and 23B. In this manner, in a normal operation in which the defective memory cell is not detected, the bit line pair BP0 as the redundancy circuit is not connected.

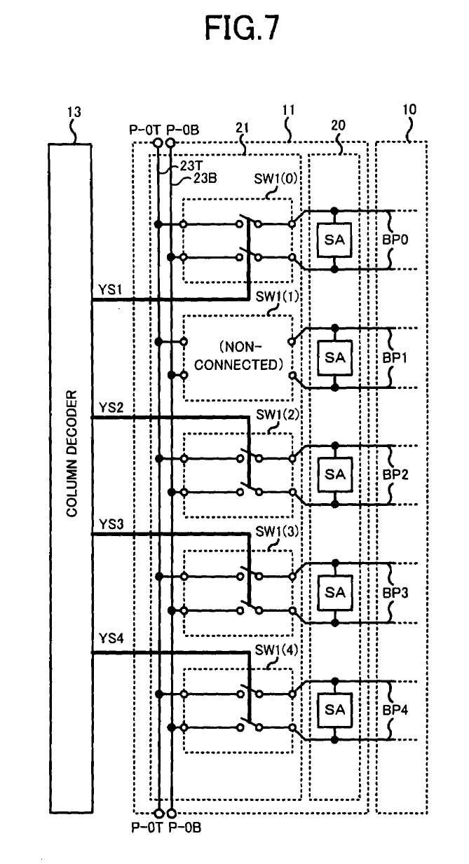

FIG. 7 is a connection state diagram corresponding to the state 1B of FIG. 5. As shown in FIG. 7, the four select control lines YS1 to YS4 are controlled to switch the four first switches SW1(0) and SW1(2) to SW1(4) except the first switch SW1(1) at the second position, and a path of the first switch SW1 is formed corresponding to one selected from the select control lines YS1 to YS4 in the same manner as described above. In this manner, when the defective memory cell is detected on the second bit line pair BP1, the bit line pair BP1 is used in a state of being shifted to the adjacent bit line pair BP0 as the redundancy circuit.

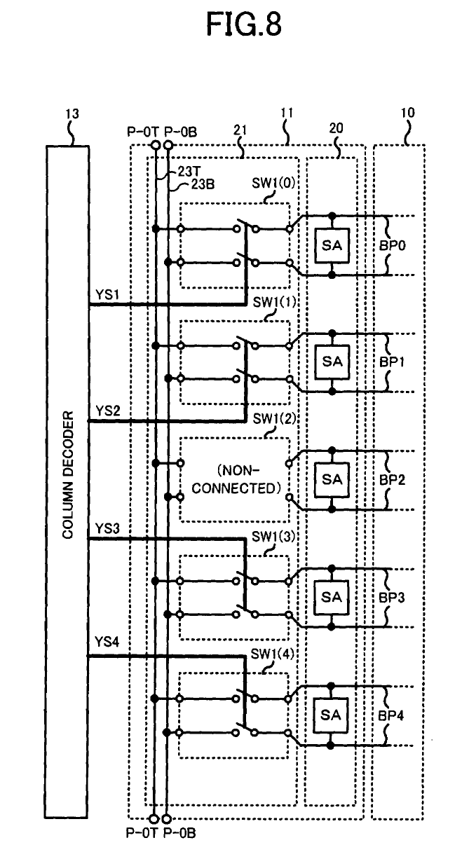

FIG. 8 is a connection state diagram corresponding to the state 1C of FIG. 5. As shown in FIG. 8 the four select control lines YS1 to YS4 are controlled to switch the four first switches SW1(0), SW1(1), SW1(3) and SW1(4) except the first switch SW1(2) at the third position, and a path of the first switch SW1 is formed corresponding to one selected from the select control lines YS1 to YS4 in the same manner as described above. In this manner, when the defective memory cell is detected on the third bit line pair BP2, two bit line pairs BP1 and BP2 are used in a state of being shifted to two bit line pairs BP0 and BP1 in a direction of the redundancy circuit.

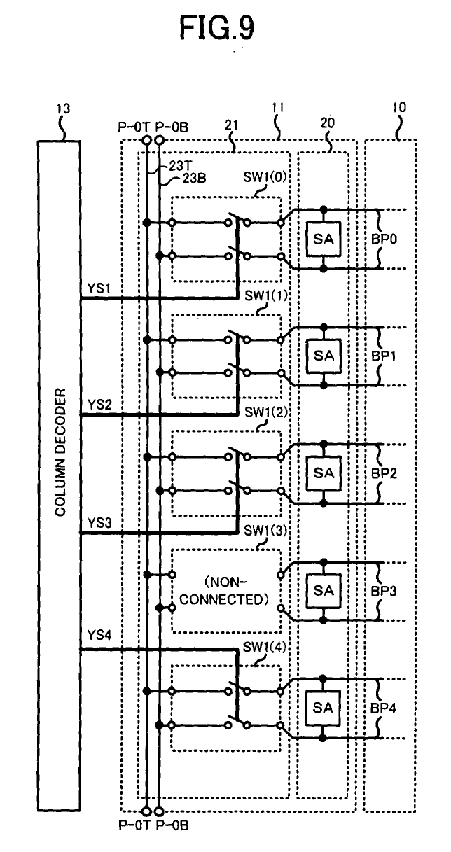

FIG. 9 is a connection state diagram corresponding to the state 1D of FIG. 5. As shown in FIG. 9, the four select control lines YS1 to YS4 are controlled to switch the four first switches SW1(0) to SW1(2) and SW1(4) except the first switch SW1(3) at the fourth position, and a path of the first switch SW1 is formed corresponding to one selected from the select control lines YS1 to YS4 in the same manner as described above. In this manner, when the defective memory cell is detected on the fourth bit line pair BP3, three bit line pairs BP1 to BP3 are used in a state of being shifted to three bit line pairs BP0 to BP2 in a direction of the redundancy circuit.

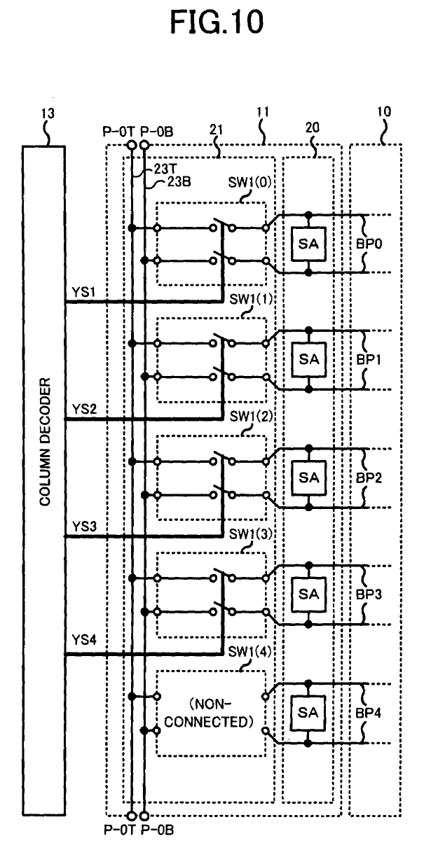

FIG. 10 is a connection state diagram corresponding to the state 1E of FIG. 5. As shown in FIG. 10, the four select control lines YS1 to YS4 are controlled to switch the four first switches SW1(0) to SW1(3) except the first switch SW1(4) at the fifth position, and a path of the first switch SW1 is formed corresponding to one selected from the select control lines YS1 to YS4 in the same manner as described above. In this manner, when the defective memory cell is detected on the fifth bit line pair BP4, four bit line pairs BP1 to BP4 are used in a state of being shifted to four bit line pairs BP0 to BP3 in a direction of the redundancy circuit.

Although the relief operation in the left side mat peripheral column circuit 11 has been described in FIGS. 6 to 10, symmetrical operation is assumed in the same manner in the right side mat peripheral column circuit 11. In this case, a defect of one bit line pair BP can be relieved by the left side mat peripheral column circuit 11, however a defect of the other bit line pair BP can be independently relieved by the right side mat peripheral column circuit 11. Thus, in the entire memory mat 10, defects of two bit line pairs BP can be relieved.

As described above, in the DRAM of the first embodiment, redundancy circuits are respectively provided to perform the relief operation for each of memory mats 10 into which the memory cell array is divided. Thus, each memory mat 10 serves as a relief unit in the DRAM of the first embodiment, and even when the defective bit line exists in a certain memory mat 10, other memory mats 10 are not affected thereby. Therefore, even when a plurality of defective bit lines is not relieved in the conventional configuration, a plurality of defective bit lines existing separately in different memory mats 10 can be individually relieved in the configuration of the first embodiment, so that relief efficiency as a whole can be improved. Further, since the shift redundancy relief method is employed in the memory mat 10, an address comparison circuit is not required and transfer time through the input/output port can be shortened by high-speed relief operation.

### Second Embodiment

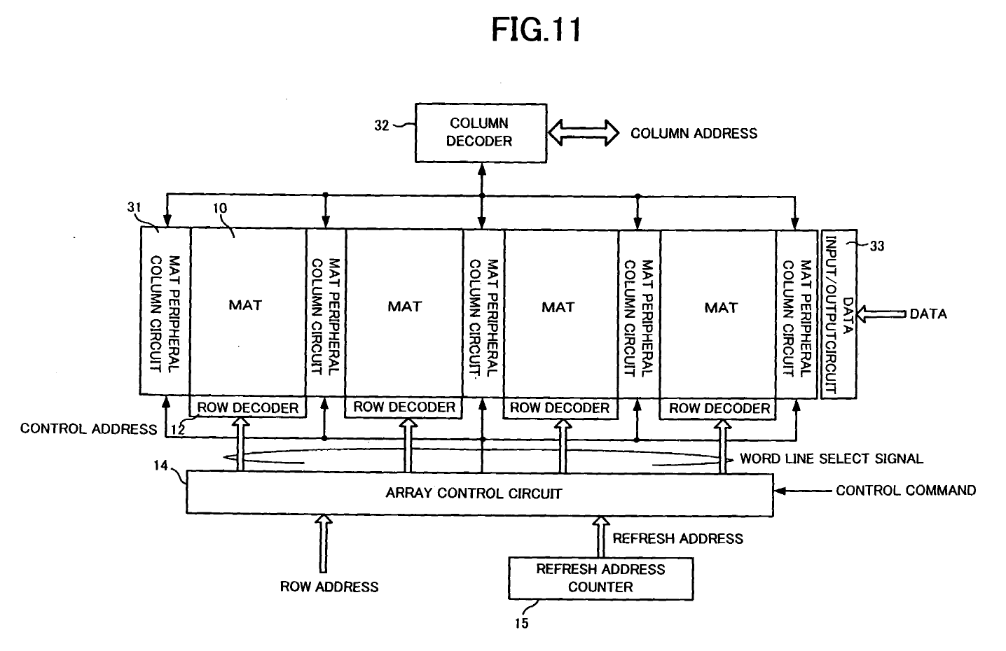

In the second embodiment, a case of applying the present invention to a DRAM having an input/output interface for internal connection having a wide bit width will be described. FIG. 11 is a diagram showing a schematic configuration of the DRAM of the second embodiment. The DRAM shown in FIG. 11 includes four memory mats 10, five mat peripheral column circuits 3l, four row decoders 12, a column decoder 32, an array control circuit 14, a refresh address counter 15 and a data input/output circuit 33. In comparison with FIG. 1 of the first embodiment, the mat peripheral column circuits 31, the column decoder 32 and the data input/output circuit 33 are configured differently, however other components are configured in the same manner as in the first embodiment, so description thereof will be omitted.

The five mat peripheral column circuits 31 are arranged in the same manner as in FIG. 1, but a switch circuit portion is configured differently as described later. The column decoder 32 is arranged at one end in a word line extending direction of the four memory mats 10, and a predetermined number of select control lines for selecting a bit line corresponding to an input column address extend in a direction orthogonal to the bit lines BL. The data input/output circuit 33 inputs/outputs data of each memory mat 10 from/to the outside via each mat peripheral column circuit 31, and input/output lines thereof extend along the direction of the bit lines BL in order to correspond to the wide bit width. Here, specific configuration and operation will be described later.

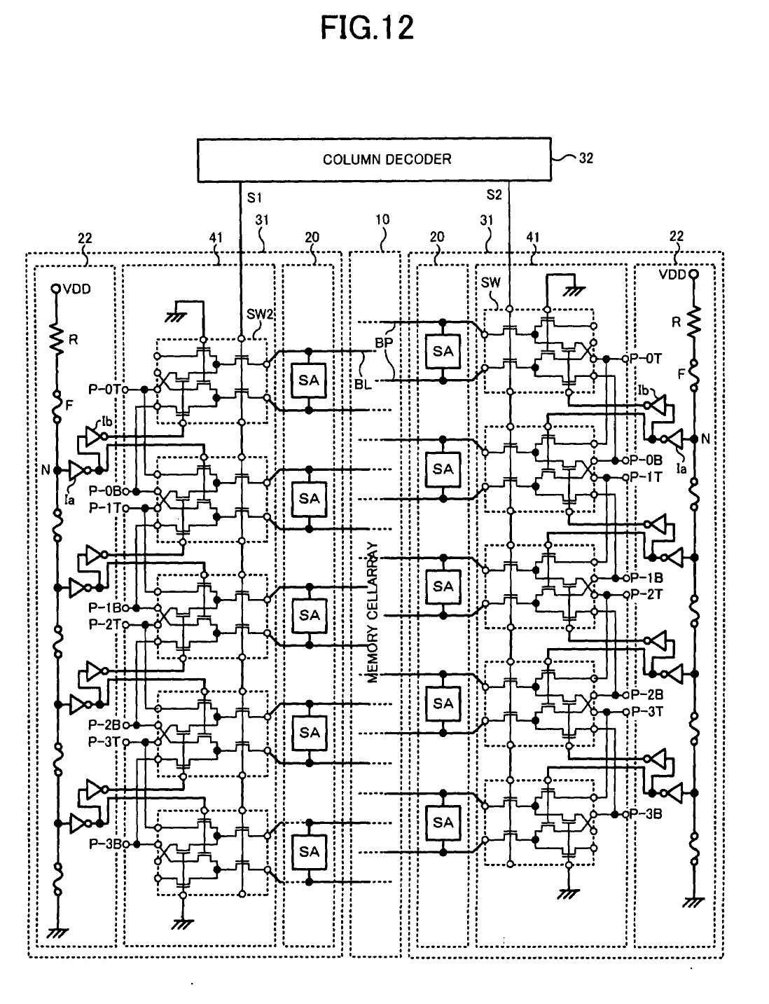

A principal configuration of the DRAM of the second embodiment will be described with reference to FIG. 12. In the following, a circuit portion including two mat peripheral column circuits 31 on both sides and the column decoder 32 will be specifically described. As shown in FIG. 12, the mat peripheral column circuit 31 is divided into a sense amplifier circuit 20, a switch circuit 41 and a fuse circuit 22. Here, the configuration of the memory mat 10 and the configuration of the sense amplifier circuit 20 and the fuse circuit 22 in the mat peripheral column circuit 31 are the same as those in the first embodiment, so description thereof will be omitted.

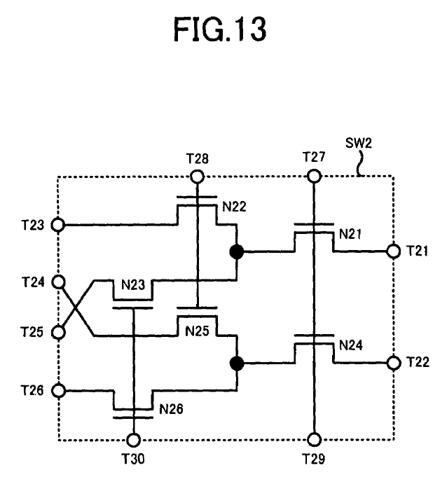

The switch circuit 41 shown in FIG. 12 includes a plurality of second switches SW2 each corresponding to the bit line pair BP. Each second switch SW2 is arranged for controlling a connection state between both ends of the sense amplifier SA corresponding to the bit line pair BP and an input/output port. Herein, a circuit configuration of the second switch SW2 is shown in an enlarged scale in FIG. 13.

As shown in FIG. 13, the second switch SW2 is composed of six NMOS transistors N21 to N26, and one pair of input terminals T21 and T22, two pairs of output terminals T23, T24 and T25, T26, and four terminals T27, T28, T29, T30 for controlling are provided therein. The input terminals T21 and T22 are connected to both ends of the sense amplifier SA, and two output terminals among the output terminals T23 to T26 are connected to the input/output port. A path from the input terminal T21 is branched into two paths via the NMOS transistor N21, one of which is connected to the output terminal T23 through the NMOS transistor N22 and the other of which is connected to the output terminal T25 through the NMOS transistor N23. Similarly, a path from the input terminal T22 is branched into two paths via the NMOS transistor N24, one of which is connected to the output terminal T24 through the NMOS transistor N25 and the other of which is connected to the output terminal T26 through the NMOS transistor N26.

Commonly connected two terminals T27 and T29 are connected to the gates of two NMOS transistors N21 and N24. The terminal T28 is connected to the gates of two NMOS transistors N22 and N25, and the terminal T30 is connected to the gates of two NMOS transistors N23 and N26. By such a configuration, two paths from the input to the output are controlled to be switched. First, when the terminal T27 (T29) and T28 are controlled to be high and the terminal T30 is controlled to be low, the input terminals T21 and T22 are connected to the upper output terminals T23 and T24. On the other hand, when the terminal T27 (T29) and T30 are controlled to be high and the terminal T28 is controlled to be low, the input terminals T21 and T22 are connected to the lower output terminals T25 and T26.

Returning to FIG. 12, connection between the both ends of the sense amplifier SA connected to the input terminals T21 and T22 and a combination of terminals of the input/output port connected to the output terminals T23 to T26 can be selectively switched by the second switch SW2 configured as in FIG. 13. By appropriately controlling the states of the terminals T27 to T30 of the five second switches SW2 included in each switch circuit 41, one of five bit line pairs BP can be always maintained in a state of being disconnected from the input/output port, as described later. In the switch circuits 41 on the both sides, the second switches SW2 have a symmetrical connection relation.

Two select control lines S1 and S2 are output from the column decoder 32 shown in FIG. 12, and one of the select control lines S1 and S2 is selectively activated in response to the column address. The two select control lines S1 and S2 extend in a direction approximately orthogonal to the direction of the bit lines BL, and one select control line S1 is commonly connected to the terminals T27 and T29 of the five second switches SW2 in the left side switch circuit 41, while the other select control line S2 is commonly connected to the terminals T27 and T29 of the five second switches SW2 in the right side switch circuit 41.

The input/output port defined in the switch circuit 41 includes four pairs of ports (each pair is composed of a T-side port and a B-side port). That is, the input/output port is composed of a pair of terminals P-0T, P-0B, a pair of terminals P-1T, P-1B, a pair of terminals P-2T, P-2B and a pair of terminals P-3T, P-3B, and transmits four bits in total. Regarding connection between each pair of ports and adjacent two second switches SW2, the T-side port is connected to one terminal T25 and the other terminal T23, while the B-side port is connected to one terminal T26 and the other terminal T24. The input/output port is commonly set for the switch circuits 41 on the both sides, and is connected to an external common node (not shown).

The fuse circuit 22 of FIG. 12 is configured and operates in the same manner as that in the first embodiment. In the adjacent two second switches SW2, an output of the first-stage inverter Ia is connected to the terminal T28 of one second switch SW2, and an output of the last-stage inverter Ib is connected to the terminal T30 of the other second switch SW2.

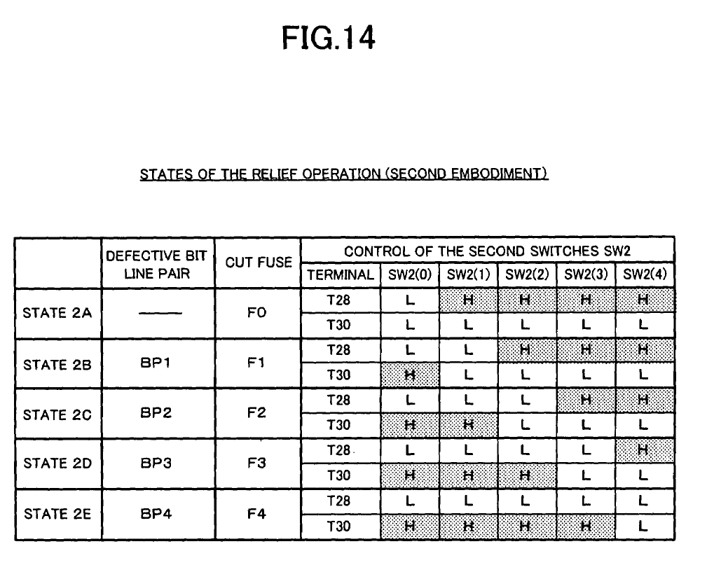

A relief operation of the mat peripheral column circuit 31 which is controlled based on the state of the fuse circuit 22 and switching of the switch circuit 41 will be described using FIGS. 14 to 19. In a table of FIG. 14, there are shown relations of positions of detected defective memory cells, positions of the bit line pairs BP, cut fuses F, control states of the terminals T28 and T30 of the second switch SW2. Here, five bit line pairs BP, five second switches SW2 and five fuses F are represented with the same numbers as in FIG. 5.

A state 2A shown in FIG. 14 corresponds to a case in which a bit line pair BP having a defective memory cell does not exist, as in FIG. 5, and the uppermost fuse F0 is cut. In the state 2A, each terminal T28 of four second switches SW2(1) to SW2 (4) is controlled to be high through the inverter Ia, and each terminal T30 of the four second switches SW2(0) to SW2(3) is controlled to be low through the inverter Ib. As shown in FIG. 12, the terminal T28 of the second switch SW2(0) and the terminal T30 of the second switch SW2(4) are both fixed to low.

Meanwhile, states 2B to 2E shown in FIG. 14 correspond to cases in which a defective memory cell is detected on any of bit line pairs BP1 to BP4, and any of fuses F1 to F4 having the corresponding number is cut. As shown in FIG. 14, as the position of the cut fuse F corresponding to the defective bit line pair changes, states of the terminals T28 and T30 change for the five second switches SW2(0) to SW2(4). In other words, terminals T28 and T30 of the second switch SW2 corresponding to the number of the cut fuse F are both controlled to be low, and on the basis of this position, second switches SW2 having smaller numbers are controlled so that the terminal T28 is low and the terminal T30 is high while second switches SW2 having larger numbers are controlled so that the terminal T28 is high and the terminal T30 is low.

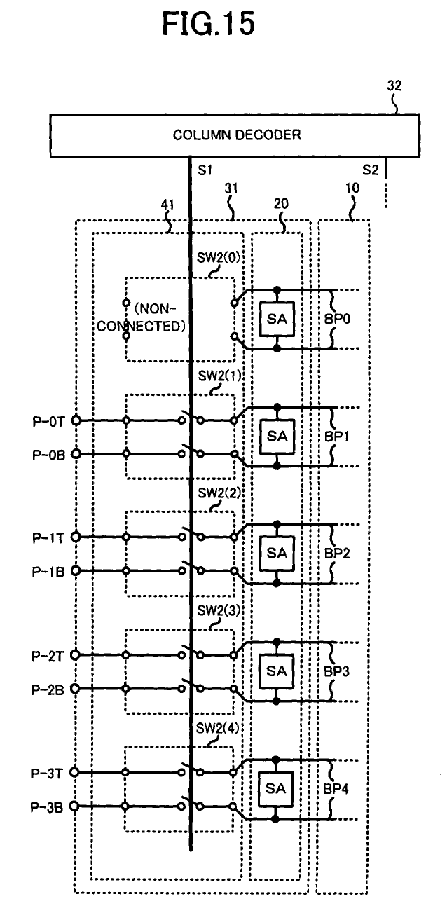

FIGS. 15 to 19 show connection states each equivalent to a circuit configuration of the left side mat peripheral column circuit 31 when the respective states 2A to 2E are controlled corresponding to the table of FIG. 14. FIG. 15 is a connection state diagram corresponding to the state 2A of FIG. 14. In FIG. 15, one select control lines S1 output from the column decoder 32 is commonly connected to all the second switches SW2(0) to SW2(4), and four pairs of terminals P-0T(B), P-1T(B), P-2T (B) and P-3T (B) are connected to paths of four second switches SW2(1) to SW2(4) in this order. Then, the input/output port is not connected to a path of the second switch SW2(0). In this manner, in the normal operation in which the defective memory cell is not detected, the bit line pair BP0 as the redundancy circuit is not connected.

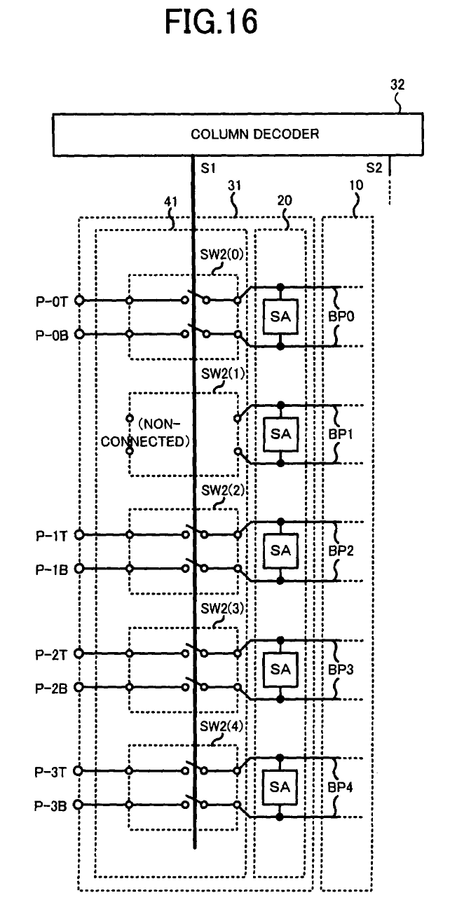

FIG. 16 is a connection state diagram corresponding to the state 2B of FIG. 14. As shown in FIG. 16, the above four pairs of terminals P-0T(B), P-1T(B), P-2T(B) and P-3T(B) are connected to paths of four second switches SW2(0) and SW2(2) to SW2(4) except the second switch SW2(1) at the second position. In this manner, when the defective memory cell is detected on the second bit line pair BP1, the bit line pair BP1 is used in a state of being shifted to the adjacent bit line pair BP0 as the redundancy circuit.

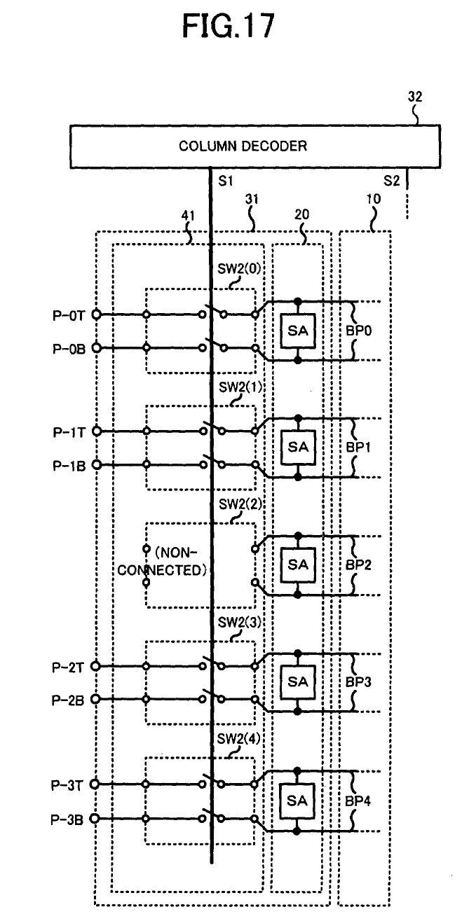

FIG. 17 is a connection state diagram corresponding to the state 2C of FIG. 14. As shown in FIG. 17, the above four pairs of terminals P-0T(B), P-1T(B), P-2T(B) and P-3T(B) are connected to paths of four second switches SW2(0), SW2(1), SW2(3) and SW2(4) except the second switch SW2(2) at the third position. In this manner, when the defective memory cell is detected on the third bit line pair BP2, two bit line pairs BP1 and BP2 are used in a state of being shifted to two bit line pairs BP0 and BP1 in a direction of the redundancy circuit.

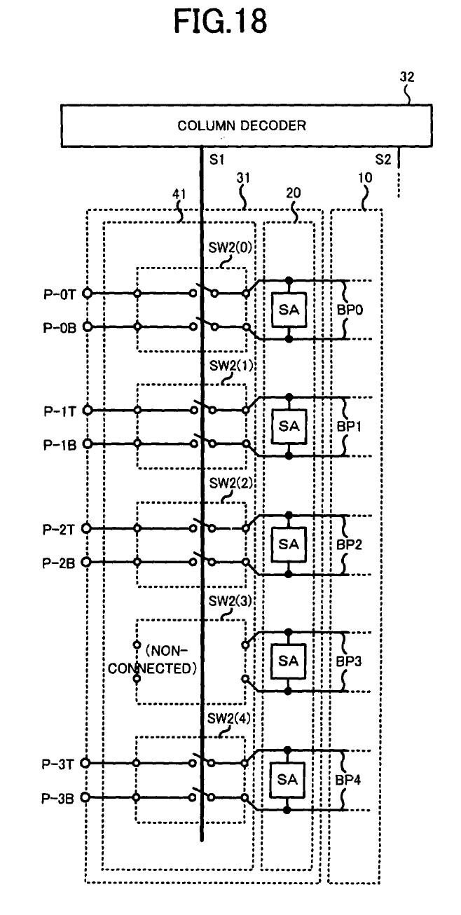

FIG. 18 is a connection state diagram corresponding to the state 2D of FIG. 14. As shown in FIG. 18, the above four pairs of terminals P-0T(B), P-1T(B), P-2T(B) and P-3T(B) are connected to paths of four second switches SW2(0) to SW2(2) and SW2(4) except the second switch SW2(3) at the fourth position. In this manner, when the defective memory cell is detected on the fourth bit line pair BP3, three bit line pairs BP1 to BP3 are used in a state of being shifted to three bit line pairs BP0 to BP2 in a direction of the redundancy circuit.

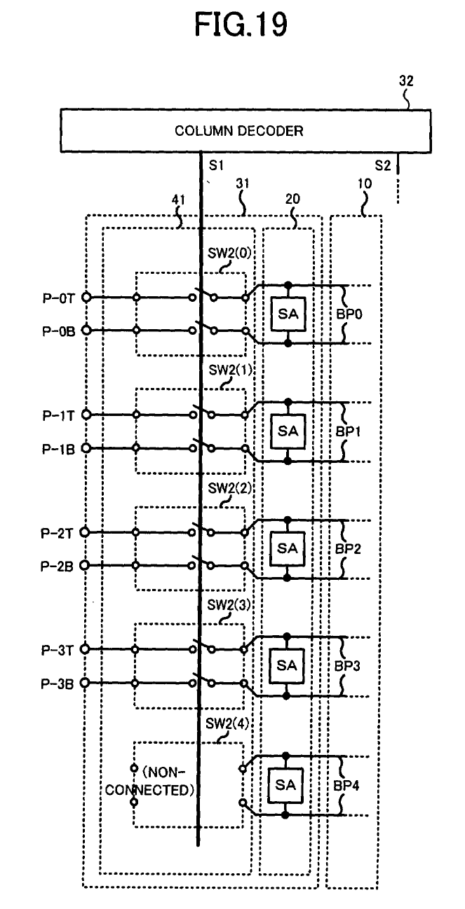

FIG. 19 is a connection state diagram corresponding to the state 2E of FIG. 14. As shown in FIG. 19, the above four pairs of terminals P-0T(B), P-1T(B), P-2T(B) and P-3T(B) are connected to paths of four second switches SW2(0) to SW2(3) except the second switch SW2(4) at the fifth position. In this manner, when the defective memory cell is detected on the fifth bit line pair BP4, four bit line pairs BP1 to BP4 are used in a state of being shifted to four bit line pairs BP0 to BP3 in a direction of the redundancy circuit.

Although the relief operation in the left side mat peripheral column circuit 31 has been described in FIGS. 15 to 19, symmetrical operation is assumed in the same manner in the right side mat peripheral column circuit 31. In this case, two bit line pairs BP, one on the left and the other on the right, can be relieved by the mat peripheral column circuits 31 on the both sides like in the first embodiment. Thus, in the entire memory mat 10, defects of two bit line pairs BP can be relieved.

As described above, in the DRAM of the second embodiment, relief efficiency can be improved in the DRAM employing the input/output port having a wide bit width, as well as the effect of the first embodiment. Therefore, particularly when the memory mat 10 is configured by arranging a large number of bit lines BL, transfer time through the input/output port can be shortened by employing the shift redundancy relief method, and it is advantageous to apply the invention to a configuration in which the DRAM circuit and the logic circuit are mixed.

### Third Embodiment

In the third embodiment, a case of applying the present invention to a DRAM having both a general input/output interface having a narrow bit width and an input/output interface for internal connection having a wide bit width will be described. It is assumed that all constituent elements in FIG. 1 of the first embodiment and in FIG. 11 of the second embodiment are provided in a schematic configuration of the DRAM of the third embodiment. Thus, two systems each having a column decoder, a switch circuit and an input/output port are provided as described later.

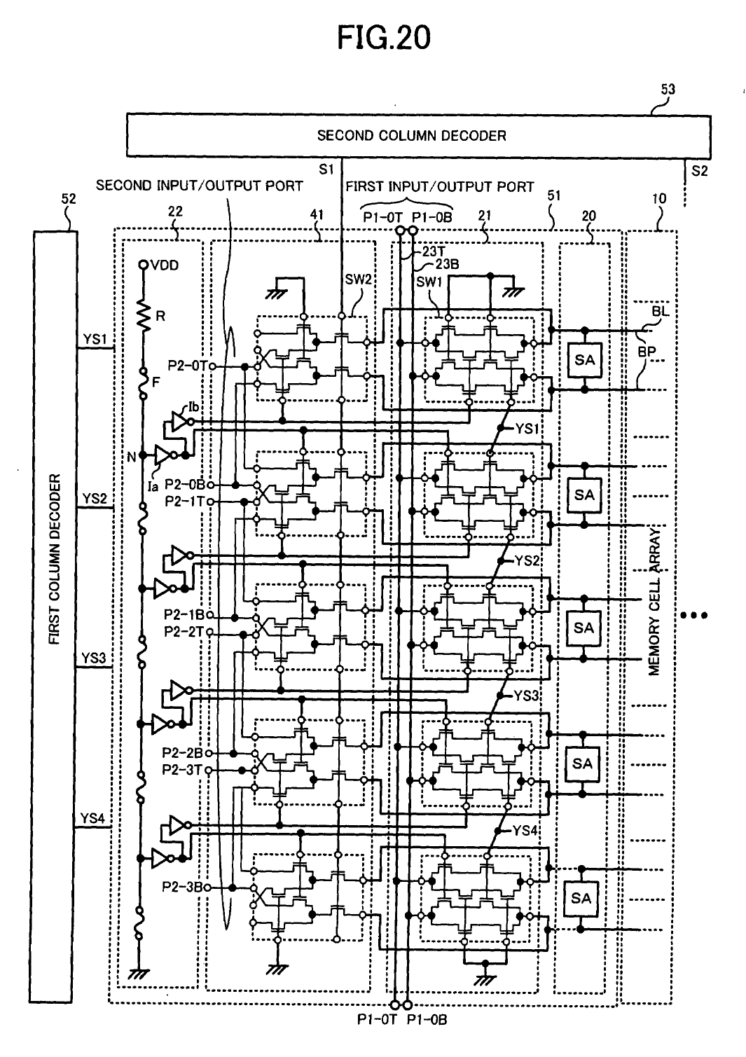

FIG. 20 is a diagram showing a principal configuration of the DRAM of the third embodiment. In the third embodiment, a mat peripheral column circuit 51 is provided in which the mat peripheral column circuit 11 of the first embodiment and the mat peripheral column circuit 31 of the second embodiment are integrally included. The mat peripheral column circuit 51 includes the sense amplifier circuit 20, the switch circuit 21 of the first embodiment, the switch circuit 41 of the second embodiment, and the fuse circuit 22. In FIG. 20, only the mat peripheral column circuit 51 on the left side of the memory mat 10 is shown, however the mat peripheral column circuit 51 is symmetrically arranged on the right side of the memory mat 10.

Respective elements in the mat peripheral column circuit 51 are the same as those in the first or second embodiment. Meanwhile, in the third embodiment, each bit line pair BP is branched in the vicinity of the sense amplifier SA, and one bit line BL thereof is connected to the input side of the first switch SW1 of the switch circuit 21, while the other bit line BL thereof is connected to the input side of the second switch SW2 of the switch circuit 41. The output side of the first switch SW1 is connected to an input/output port defined in the same manner as in the first embodiment (hereinafter referred to as “first input/output port”), and the output side of the second switch SW2 is connected to an input/output port defined in the same manner as in the second embodiment (hereinafter referred to as “second input/output port”). Here, respective terminals of the first input/output port are denoted by P1-0T(B), and respective terminals of the second input/output port are denoted by P2-0T(B), P2-1T(B), P2-2T(B) and P2-3T(B).

Four select control lines YS1 to YS4 are output from a first column decoder 52 corresponding to the column decoder 13 of the first embodiment, and are connected to adjacent two first switches SW1 having different combinations from one another. Meanwhile, select control lines S1 and S2 are output form a second column decoder 53 corresponding to the column decoder 32 of the second embodiment, and among them, the select control line S1 is commonly connected to five second switches SW2.

The fuse circuit 22 has the same configuration as that in the first and second embodiments, and its path is branched into two at the output side of the two-stage inverters Ia and Ib, one of which is connected to the terminals T16 and T18 of the first switch SW1 while the other of which is connected to the terminals T28 and T30 of the second switch SW2. Thus, by selectively cutting the fuse F of the fuse circuit 22, connection states of the first and second input/output ports for each bit line pair BP can be controlled at the same time.

In a specific relief operation of the mat peripheral column circuit 51 in the third embodiment, FIGS. 5 to 10 in the first embodiment and FIGS. 14 to 19 in the second embodiment are reflected.

Next, a modification based on the configuration of the third embodiment will be described, in which a semiconductor device is configured by a DRAM circuit mixed with a logic circuit. The memory mat 10 and the mat peripheral column circuits 51 on both sides thereof serve as a basic unit (hereinafter referred to as “memory block”), and a large number of memory blocks are arranged together with the logic circuit so that a large scale DRAM macro circuit can be configured.

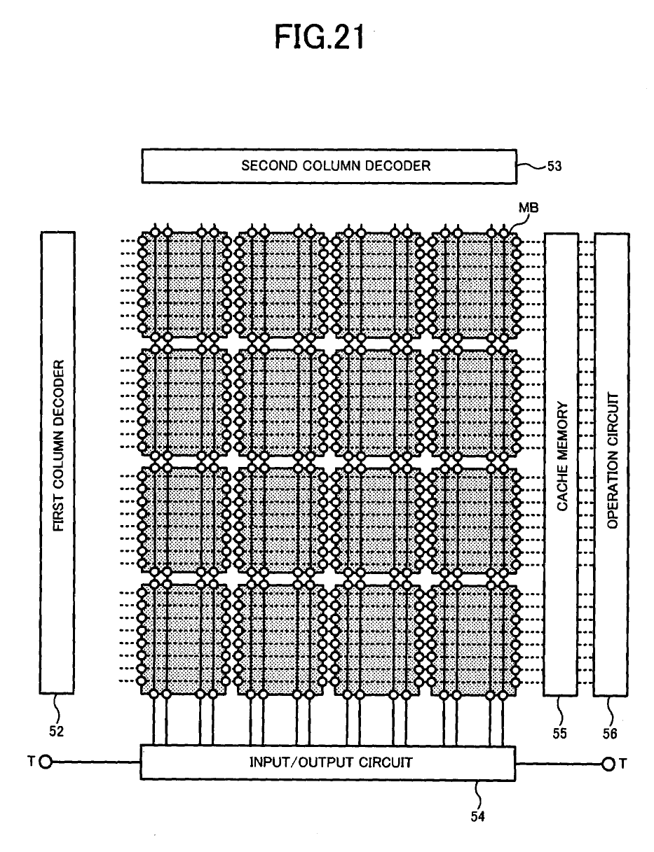

FIG. 21 is a diagram showing a configuration example of the DRAM macro circuit. In the configuration example of FIG. 21, a total of sixteen memory blocks MB each including the memory mat 10 and the mat peripheral column circuits 51 on the both sides are arranged (four in a longitudinal direction and four in a lateral direction). Around the sixteen memory blocks, there are arranged the above mentioned first column decoder 52 and second column decoder 53, an input/output circuit 54, a cache memory 55 and an operation circuit 56 as additional circuits to the DRAM circuit.

In FIG. 21, the first and second input/output ports of FIG. 20 are represented by small circles at outer edges of the respective memory blocks MB. Further, longitudinal solid lines represent the input/output lines 23T and 23B (see FIG. 3) of the first input/output port, and lateral dotted lines represent input/output lines (generally formed in a layer over the memory cell array 10) of the second input/output port. Other constituent elements are omitted in FIG. 21.

As shown in FIG. 21, four memory blocks MB arranged in the longitudinal direction include the input/output lines 23T and 23B commonly connected to one another. Further, four memory blocks MB arranged in the lateral direction include the input/output lines of the second input/output port commonly connected to one another. Thus, the first input/output port has a bit width of 8 bits, and the second input/output port has a bit width of 16 bits. Further, the number of select control lines (not shown) of the first column decoder 52 is sixteen, and the number of select control lines (not shown) of the second column decoder 53 is eight.

The input/output circuit 54 is connected to one end of the first input/output port, and two input/output terminals T connected to the input/output circuit 54 are provided. The input/output circuit 54 controls data input/output from/to the outside through the input/output terminals T. In this case, the bit width of the first input/output port is determined according to the specification of the general DRAM interface.

Meanwhile, the operation circuit 56 is connected to one end of the second input/output port via the cache memory 55. The operation circuit 56 performs a predetermined operation process using data transferred from the second input/output port to the cache memory 55. The bit width of the second input/output port increases according to the number of the bit lines BL so as to be suitable for a high-speed operation process using large capacity data such as image processing. Data corresponding to an operation result of the operation circuit 56 can be written back to the memory block MB through the cache memory 55.

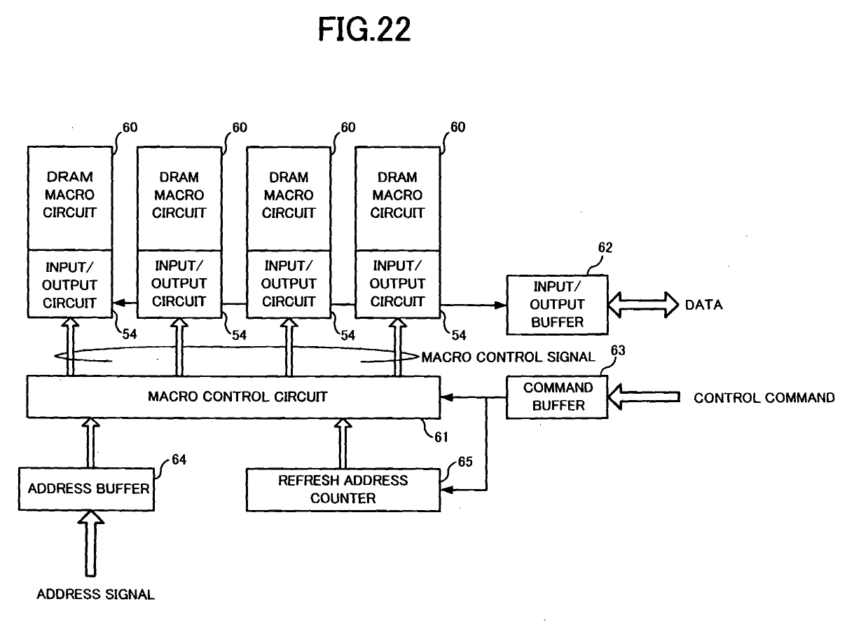

FIG. 22 is a diagram showing an example of an entire configuration of the semiconductor device including the DRAM macro circuit of FIG. 21. The semiconductor device as shown in FIG. 22 is configured by the four DRAM macro circuits 60 as the basic units and includes the above input/output circuits 54 attached to the respective DRAM macro circuits 60, a macro control circuit 61, an input/output buffer 62, a command buffer 63, an address buffer 64 and a refresh address counter 65, and is entirely configured on the same chip.

In FIG. 22, each of the four DRAM macro circuits 60 has the configuration of FIG. 21, and the entire operation thereof is controlled by the macro control circuit 61. Four input/output circuits 54 attached to the four DRAM macro circuits 60 are commonly connected to one another and the input/output buffer 62 is connected thereto. Data is input/output between the semiconductor device and the outside through the input/output buffer 62. Further, a control command input from the outside is stored in the command buffer 63, and a macro control signal corresponding to the control command is output by the macro control circuit 61. An address signal input from the outside is stored in the address buffer 64 and sent to the macro control circuit 61. In this case, the address signal includes addresses for selecting the four DRAM macro circuits 60 in addition to the row address and the column address. Meanwhile, when a refresh command is input, a refresh address is counted by the refresh address counter 65.

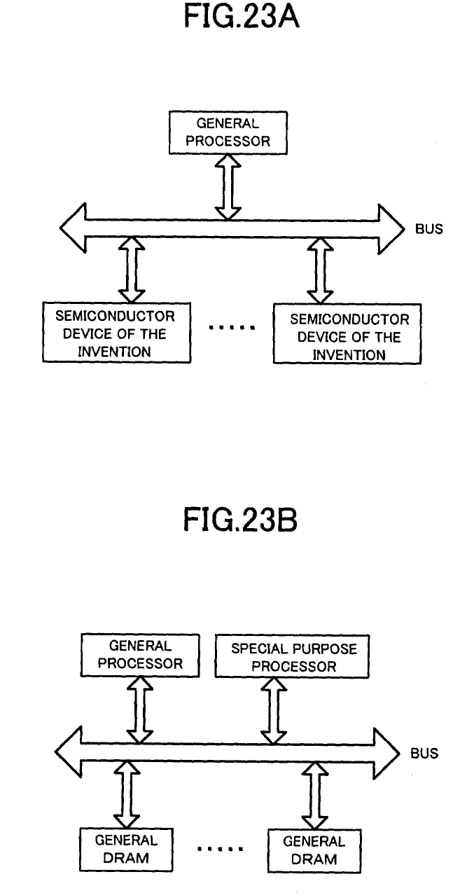

In the configuration of the semiconductor device of FIG. 22, the first input/output port having a narrow bit width and the second input/output port having a wide bit width can be used at the same time, and which can be used separately while controlling the relief operation for both the first and second ports by the redundancy circuit. Further, a system can be constructed by implementing the semiconductor device shown in FIG. 22. FIG. 23A shows an example of the system using the semiconductor device shown in FIG. 22, and FIG. 23B shows an example of a system using the conventional general DRAM for comparison with FIG. 23A.

In the system of FIG. 23A, a plurality of the semiconductor devices of FIG. 22 and one general processor are connected to a common bus. In this case, data transfer on the bus is performed between the plurality of the semiconductor devices and the general processor through the first input/output ports, while inside the semiconductor devices, high-speed data transfer from/to the logic circuit is performed through the second input/output ports. On the other hand, in FIG. 23B, one special purpose processor serving as the above-mentioned logic circuit is connected to the bus as well as a plurality of general DRAMs and one general processor. Thus, since high-speed data transfer between each general DRAM and the special purpose processor is performed through an external bus, bus bottleneck occurs in the configuration of FIG. 23B. Accordingly, employment of high-speed bus and implementation of a high-performance special purpose processor are required, and increases in consumption current and cost cannot be avoided. On the contrary, high-speed bus and high-performance special purpose processor is not required in the configuration of FIG. 23A, and therefore reductions in consumption current and cost can be achieved in comparison with FIG. 23B.

As described above, the DRAM of the third embodiment is useful for a combined configuration of both the first and second embodiments. In this case, relief efficiency is improved by dividing into a large number of memory mats 10, and the entire semiconductor device can be configured in which the first input/output port having a narrow bit width and the second input/output port having a wide bit width are used separately. Particularly, the first input/output port having a narrow bit width is used as a general DRAM interface and the second input/output port having a wide bit width are used for connection to an internal logic circuit, and thereby realizing an optimal configuration in which the DRAM circuit and the logic circuit are mixed.

In the foregoing, the present invention is specifically described based on the embodiments. However, the present invention is not limited to the above described embodiments, and can be variously modified without departing the essentials of the present invention. Since a case in which the present invention is applied to a semiconductor device including a DRAM circuit is described in the embodiments, the present invention is not limited to this case and can be widely applied to a semiconductor device having a variety of memory circuits to which the relief operation of the embodiments can be applied, or to a semiconductor device in which such a memory circuit and a logic circuit are mixed.

The present invention is not limited to the above described embodiments, and various variations and modifications may be possible without departing from the scope of the present invention.

This application is based on the Japanese Patent application No. 2006-275823 filed on Oct. 6, 2006, entire content of which is expressly incorporated by reference herein.

What is claimed is:

1. A semiconductor device having a memory cell array in which a plurality of memory cells are formed at intersections between a plurality of word lines and a plurality of bit lines, comprising:
a plurality of unit blocks aligned at least in a bit line extending direction, into which the memory cell array is divided;
a plurality of sense amplifiers provided in each of said unit blocks for amplifying data of the memory cells through the bit lines;
a switch circuit capable of switching connection between an input/output port for inputting/outputting data of said unit blocks and said plurality of sense amplifiers; and
a redundancy select circuit for controlling said switch circuit so as to maintain connection relation between the input/output port and a predetermined number of the sense amplifiers from which one or more sense amplifiers each corresponding to a defective bit line having a defective memory cell are excluded, in accordance with defect information specifying the defective memory cell in said unit blocks.

2. The semiconductor device according to claim 1, wherein said redundancy select circuit is connected to said switch circuit through a node between adjacent fuses among a plurality of fuses connected in series between a power supply and ground, and is configured such that one fuse selected based on said defect information is cut.

3. The semiconductor device according to claim 1, wherein two bit lines as a complementary pair constitute a bit line pair, the memory cell is formed at one of two intersections between the bit line pair and the word line, and each of the sense amplifiers is arranged corresponding to the bit line pair.

4. The semiconductor device according to claim 3, wherein the input/output port has a plurality of terminals and a pair of the terminals corresponding to the bit line pair transmits one bit through the sense amplifier.

5. The semiconductor device according to claim 4 further comprising a column decoder for selectively activating a plurality of select control lines extending along the plurality of bit lines in response to an input column address,
wherein said switch circuit includes a plurality of first switches capable of switching connection between the sense amplifier and the pair of the terminals in response to the select control line selected among adjacent two select control lines by said redundancy select circuit.

6. The semiconductor device according to claim 4 further comprising a column decoder for selectively activating a plurality of select control lines extending in an intersecting direction of the plurality of bit lines in response to an input column address,
wherein said switch circuit includes a plurality of second switches capable of switching connection between the terminal selected among adjacent two pairs of terminals by said redundancy select circuit and the sense amplifier in response to the select control line commonly connected thereto.

7. The semiconductor device according to claim 3, wherein said plurality of sense amplifiers, said switch circuit and said redundancy select circuit are symmetrically arranged at both ends in a bit line extending direction of said unit blocks, and each of the bit line pair is connected to one of the sense amplifiers at the both ends.

8. The semiconductor device according to claim 7, wherein said plurality of sense amplifiers, said switch circuit and said redundancy select circuit are shared by adjacent two of said unit blocks.

9. The semiconductor device according to claim 3, wherein one bit line pair and one sense amplifier among the N+1 bit line pairs and corresponding N+1 said sense amplifiers are provided as a redundancy circuit,
and said redundancy select circuit controls said switch circuit so as to maintain connection relation between N said sense amplifiers and the input/output port by replacing one defective bit line pair and one corresponding sense amplifier with the redundancy circuit.

10. A semiconductor device having a memory cell array in which a plurality of memory cells are formed at intersections between a plurality of word lines and a plurality of bit lines, comprising:
a plurality of unit blocks aligned at least in a bit line extending direction, into which the memory cell array is divided;
a plurality of sense amplifiers provided in each of said unit blocks for amplifying data of the memory cells through the bit lines;
a first switch circuit capable of switching connection between a first input/output port for inputting/outputting data of said unit blocks and said plurality of sense amplifiers;
a second switch circuit capable of switching connection between a second input/output port for inputting/outputting data of said unit blocks and said plurality of sense amplifiers; and
a redundancy select circuit for controlling said first switch circuit so as to maintain connection relation between the first input/output port and a predetermined number of the sense amplifiers from which one or more sense amplifiers each corresponding to a defective bit line having a defective memory cell are excluded, and connection relation between the second input/output port and the predetermined number of the sense amplifiers, in accordance with defect information specifying the defective memory cell in said unit blocks.

11. The semiconductor device according to claim 10 further comprising:
a first column decoder for selectively activating a plurality of first select control lines extending along the plurality of bit lines in response to an input column address; and
a second column decoder for selectively activating a plurality of second select control lines extending in an intersecting direction of the plurality of bit lines in response to an input column address,
wherein said first switch circuit is switched by the first select control lines and said second switch circuit is switched by the second select control lines.

12. The semiconductor device according to claim 11, wherein a bit width of the second input/output port is larger than a bit width of the first bit input/output port.

13. The semiconductor device according to claim 11, wherein a memory block including said unit blocks, said plurality of sense amplifiers, said first switch circuit, said second switch circuit and said redundancy select circuit is configured, and a memory circuit is configured by arranging said first column decoder and said second column decoder for a plurality of the memory blocks.

14. The semiconductor device according to claim 13, wherein the plurality of the memory blocks is arranged in a bit line extending direction and in a direction orthogonal to the bit lines, the respective first input/output ports thereof are connected to one another through common input/output lines, and the respective second input/output ports thereof are connected to one another through common input/output lines.

15. The semiconductor device according to claim 13, wherein the first input/output port is connected to outside and the second input/output port is connected to an internal logic circuit.
